(19) United States
(12) Patent Application Publication
(10) Pub. No.: US 2020/0209722 A1
(43) Pub. Date: Jul. 2, 2020

(54) NOVEL LCD PROJECTOR

(71) Applicant: Yi Xu, Pujiang (CN)

(72) Inventor: Yi Xu, Pujiang (CN)

(21) Appl. No.: 16/261,591

(22) Filed: Jan. 30, 2019

(30) Foreign Application Priority Data
Dec. 27, 2018 (CN) 201811615431.3

(51) Int. Cl. G03B 21/16; G02F 1/1335; H01L 33/58; H05K 7/20; G03B 21/00; G03B 21/20

(52) U.S. Cl. CPC G03B 21/16; G02F 1/133603; H01L 33/58; G02F 1/13362; G02F 2001/133628; H05K 7/20154; G03B 21/006; G03B 21/2073; H05K 7/202

(57) ABSTRACT

The invention discloses a novel LCD projector, comprising an imaging system with a sealed shell of the LCD projector, an illumination system with PCS function and transparent antifouling coating, and an LED light source system, wherein the sealed shell is provided with lens, optical, and first radiator assemblies. The invention is disposed in a sealed shell; a heat dissipation assembly is installed at the liquid crystal display outlet. The optical device can be positioned in a dust-free environment for the sealed shell. The useless P light for conventional LCD projector imaging is converted into the useful S light, improving light utilization and increasing projection brightness under the same power. The transparent antifouling coating is applied to the illumination section, reducing dust absorption and improving system cleanliness. A microlens is used to converge the LED light source in the LED illumination section, improving light effects and uniformity.

### BACKGROUND OF THE INVENTION

### 1. Field of the Invention

The invention relates to a projector, and in particular, to a novel LCD projector.

### 2. Description of the Related Art

An LCD projector is an optical instrument that uses optical components to magnify an LCD display and project it onto a screen, which is widely used in the field of large-size display.

When the LCD projector is in use, the optical device generates a large amount of heat, which seriously affects the service life of the LCD projector and the stability of usage, therefore, the LCD projector needs to be blown from the outside with air by the fan to be cooled, which causes the problem of dirty and black spots inside the system after being used for a period of time, affecting the display effect. Moreover, the lights emitted by the light source of conventional projectors contain two polarized lights: P light and S light, but the LCD projector can only use one of the polarized lights, and the illumination system is simple in structure, the overall light effect is not high, which causes the high power and low brightness of the prior projectors.

The technical issue to be solved by the invention is to provide a novel LCD projector, adopting a sealed internal circulation heat dissipation system, an illumination system with PCS function and transparent antifouling coating, and an LED light source with microlens array, which can effectively solve the shortcomings in the prior art.

The invention is achieved by the following technical solutions: a novel LCD projector, comprising an imaging system with a sealed shell of the LCD projector, an illumination system with PCS function and transparent antifouling coating, and an LED light source system, wherein the sealed shell is provided with a lens assembly, an optical assembly, and a first radiator assembly; the LED light source system comprises a microlens array molded from the resin, an array of LED chips, a second radiator assembly and a second fan.

As a preferred technical solution, the imaging system of the sealed shell comprises a bottom shell and a first face shell; a first fan, a heat absorption end of the first radiator assembly, a first retroreflector, a second Fresnel lens, a liquid crystal display, and a reflective polarizing film are installed in the shell; the heat absorption end of the first radiator assembly is installed at the side of the air outlet of the liquid crystal display; the outside of the shell is provided with a heat dissipation end of the first radiator assembly, an illumination assembly and a light source assembly, and the heat dissipation end of the first radiator is installed at the side of the air inlet of the second fan.

As a preferred technical solution, the optical assembly and the illumination assembly comprise a first retroreflector, a second Fresnel lens, a reflective polarizing film, a liquid crystal display, a first Fresnel lens, a second retroreflector with a ¼ wave plate, and a lens assembly; the liquid crystal display, the second Fresnel lens, the first retroreflector, and the lens assembly are sequentially installed at one side of the reflective polarizing film; the first retroreflector is obliquely disposed at one side of the reflective polarizing film, and the reflective surface of the first retroreflector is disposed directly facing the lens assembly; the first Fresnel lens, the light source assembly, and the second retroreflector with a ¼ wave plate are disposed at the other side of the reflective polarizing film, and the light source assembly and the second retroreflector with a ¼ wave plate are arranged in parallel.

As a preferred technical solution, the sealed shell comprises a bottom shell and a first face shell, and a sheet metal is mounted at the top of the first face shell.

As a preferred technical solution, the microlens array is molded from the resin.

As a preferred technical solution, the heat dissipation end of the first radiator and the second radiator share the air channel and the second fan.

As a preferred technical solution, the reflective polarizing film is a part of the sealed shell and is not parallel to the liquid crystal display, and a small included angle is formed between the reflective polarizing film and the liquid crystal display.

As a preferred technical solution, the transparent antifouling coating is applied to the reflective polarizing film and the first Fresnel lens.

As a preferred technical solution, the second retroreflector with a ¼ wave plate may be a flat retroreflector or a curved retroreflector.

As a preferred technical solution, the light source assembly comprises an LED array with microlenses, a second radiator and a second fan; the divergent lights emitted by the light source are irradiated on the first Fresnel lens after passing through the microlens, then are irradiated on the reflective polarizing film after being converted into the parallel light through the first Fresnel lens; S light is transmitted, and P light is reflected; the reflected P light is converged on the second retroreflector with a ¼ wave plate through the first Fresnel lens.

As a preferred technical solution, each of the LED chips in the LED array of the light source assembly is provided with a microlens, and the microlens is a freeform lens which converges the lights emitted by the LED chip into uniform faculae with the shape and size of the liquid crystal display.

The invention has the advantageous effects as follows: 1. the invention is disposed in a sealed shell, so that the optical device can be positioned in a dust-free environment, which solves the problem that the conventional LCD projector machine is prone to dirty and black spots after being used for a period of time; simultaneously, the reflective polarizing film is a part of the sealed shell, and a large amount of heat is left outside the shell, which reduces the amount of heat dissipation of the sealed shell. Meanwhile, the transparent antifouling coating is applied to the reflective polarizing film and the first Fresnel lens, which can reduce the adsorption of dust and improve the cleanliness of the system; and the first heat sink is disposed at the air outlet of the liquid crystal display, which is beneficial to improving the heat dissipation efficiency.

2. The P light that is useless for imaging of the conventional LCD projector is converted into the useful S light, which improves the utilization of light and greatly increases the brightness of the projection under the same power.

3. The microlens and the LED chip are in one-to-one correspondence, which can improve the utilization efficiency of the LED light source and the uniformity of the illumination.

### BRIEF DESCRIPTION OF THE DRAWINGS

In order to more clearly illustrate the embodiments of the invention or the technical solutions in the prior art, the drawings used in the embodiments or the description in the prior art will be briefly described hereinafter. It is obvious that the drawings in the following description are only some embodiments of the invention, and those skilled in the art can obtain other drawings based on these drawings without any creative efforts.

FIG. 1 is a schematic diagram illustrating the overall structure of the invention.

FIG. 2 is an overall exploded diagram illustrating the invention.

FIG. 3 is an overall optical diagram illustrating the invention.

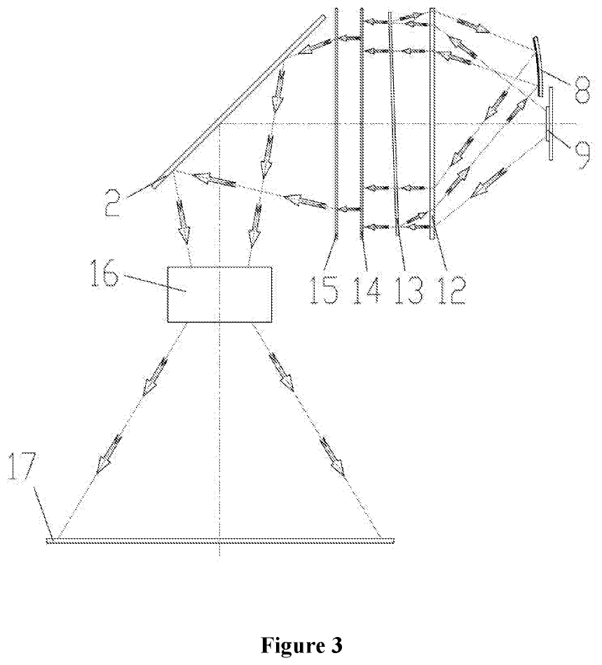

FIG. 4 is a schematic diagram illustrating the polarizing light conversion structure of the illumination assembly of the invention.

FIG. 5 is a schematic diagram illustrating the structure of the light source assembly of the invention.

FIG. 6 is an optical schematic of the light source assembly of the invention.

### REFERENCE NUMERALS

1 refers to the bottom shell; 2 refers to the retroreflector; 3 refers to the first fan; 4 refers to the first face shell; 5 refers to the aluminum board; 6 refers to the second face shell; 7 refers to the second radiator assembly; 8 refers to the second retroreflector with a ¼ wave plate; 9 refers to the light source assembly; 10 refers to the second fan; 11 refers to the first radiator assembly; 12 refers to the first Fresnel lens; 13 refers to the reflective polarizing film; 14 refers to the liquid crystal display; 15 refers to the second Fresnel lens; 16 refers to the lens assembly; 17 refers to the curtain; 18 refers to the base board; 19 refers to the microlens; 20 refers to the LED chip.

### DETAILED DESCRIPTION OF THE PREFERRED EMBODIMENTS

All of the features disclosed in the specification, or steps in all methods or processes disclosed, may be combined in any manner other than mutually exclusive features and/or steps.

Any feature disclosed in the specification (including any appended claims, abstract and drawings) may be replaced by other equivalents or alternatives, unless otherwise stated. That is, unless specifically stated, each feature is only one example of a series of equivalent or similar features.

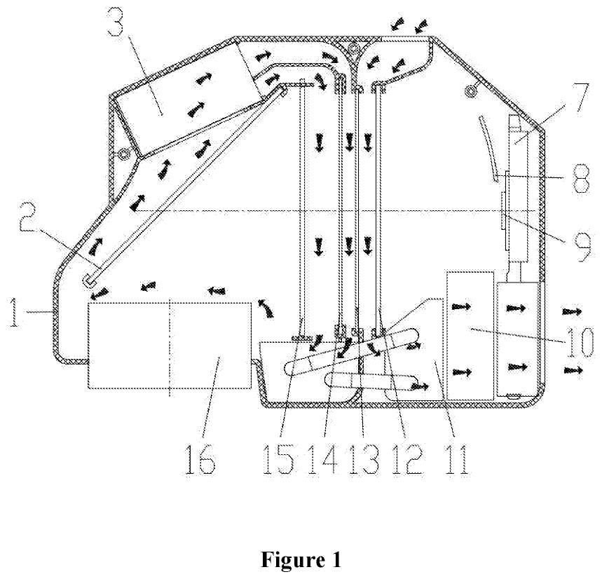

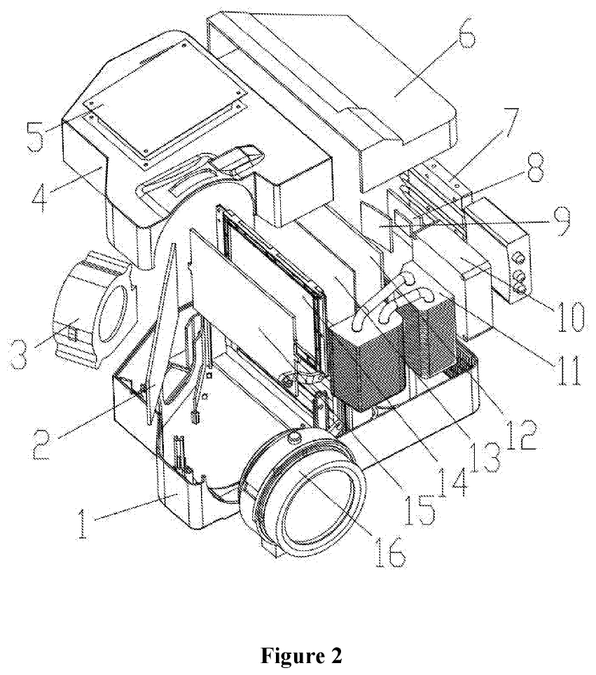

As shown in FIGS. 1 and 2, the projector comprises an imaging system with a sealed shell of the LCD projector, an illumination system with PCS function and transparent antifouling coating, and an LED light source system with a microlens array, wherein the sealed shell is provided with a lens assembly 16 and a first radiator assembly 11; the illumination system comprises an illumination assembly with PCS function and transparent antifouling coating; the light source system comprises a microlens array molded from the resin, an array of LED chips, a second radiator assembly 7 and a second fan 10.

The imaging system of the sealed shell comprises a sealed bottom shell 1 and a sealed first face shell 4, and an aluminium board 5 is mounted on the first face shell 4; a first fan 3, a heat absorption end of the first radiator assembly 11, a first retroreflector 2, a second Fresnel lens 15, a liquid crystal display 14, and a reflective polarizing film 13 are installed in the shell; the heat absorption end of the first radiator assembly 11 is installed at the side of the air outlet of the liquid crystal display 14; the outside of the shell is provided with a heat dissipation end of the first radiator assembly 11, an illumination assembly and a light source assembly 9, and the heat dissipation end of the first radiator assembly 11 is installed at the side of the air inlet of the second fan 10.

The optical assembly comprises a first retroreflector 2, a second Fresnel lens 15, a reflective polarizing film 13, a liquid crystal display 14, a first Fresnel lens 12, a second retroreflector with a ¼ wave plate 8, and a lens assembly 16; the liquid crystal display 14, the second Fresnel lens 15, the first retroreflector 2, and the lens assembly 16 are sequentially installed at one side of the reflective polarizing film 13, and the first Fresnel lens 12, the light source assembly 9, and the second retroreflector with a ¼ wave plate 8 are disposed at the other side of the reflective polarizing film 13, and the light source assembly 9 and the second retroreflector with a ¼ wave plate 8 are arranged in parallel; the first retroreflector 2 is obliquely disposed at one side of the reflective polarizing film 13, and the reflective surface of the first retroreflector 2 is disposed directly facing the lens assembly 16.

In the embodiment, the reflective polarizing film 13 is a part of the sealed shell. The reflective polarizing film 13 is not parallel to the liquid crystal display 14, and a small included angle is formed between the reflective polarizing film 13 and the liquid crystal display 14. The heat dissipation end of the first radiator 11 and the second radiator 7 share the air channel and the second fan 10.

In the embodiment, the second retroreflector with a ¼ wave plate 8 may be a flat retroreflector or a curved retroreflector.

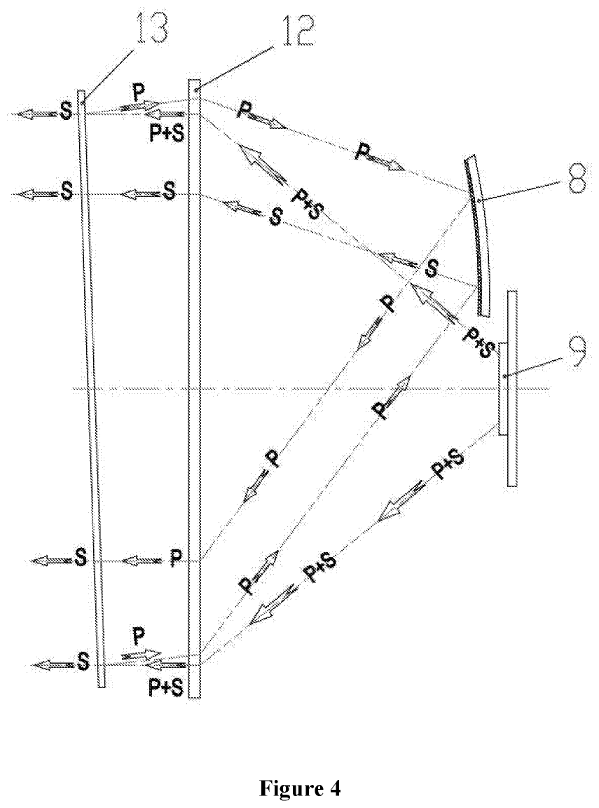

As shown in FIG. 4, the illumination assembly comprises a reflective polarizing film 13, a first Fresnel lens 12, and a second retroreflector with a ¼ wave plate 8; the light source assembly 9 comprises an LED array with microlenses, a second radiator 7 and a second fan 10; the divergent lights emitted by the light source are irradiated on the first Fresnel lens 12 after passing through the microlens 19, then are irradiated on the reflective polarizing film 13 after being converted into the parallel light through the first Fresnel lens 12; S light is transmitted, and P light is reflected; the reflected P light is converged on the second retroreflector with a ¼ wave plate 9 through the first Fresnel lens 12. Since the ¼ wave plate has a function of converting P light into S light, all of the lights reflected to the reflective polarizing film 13 are S light, and all of them can pass through the reflective polarizing film 13 and can be irradiated onto the liquid crystal display 14. The process is also suitable for converting the mixed light of P light and S light emitted from the LED into the pure P light.

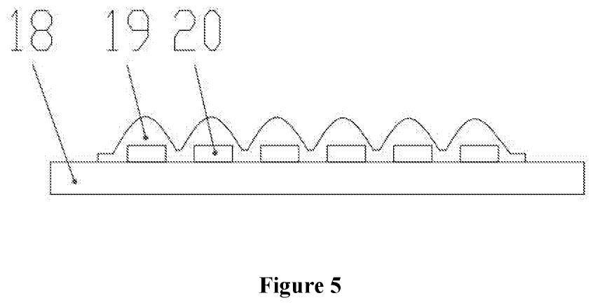

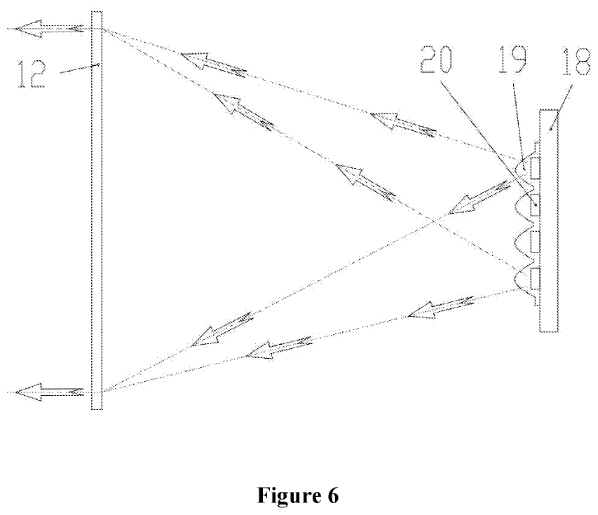

As shown in FIGS. 5 and 6, each of the LED chips 20 in the LED array of the light source assembly is provided with a microlens 19, and the microlens 19 is a freeform lens which converges the lights emitted by the LED chip 20 into uniform faculae with the shape and size of the liquid crystal display 14. Each of the microlenses 19 can accurately project the corresponding LED chip 20 onto the first Fresnel lens 12 according to the expected size, shape and uniformity. Since the position of each of the LED chips 20 is different, therefore, the shape and angle of each of the LED microlenses 19 is different.

The above is only the specific embodiment of the invention, but the protection scope of the invention is not limited thereto, and any changes or substitutions without creative efforts shall all fall within the protection scope of the invention. Therefore, the protection scope of the invention should be subject to the protection scope defined by the appended claims.

1. A novel LCD projector, comprising an imaging system with a sealed shell of the LCD projector, an illumination system with PCS function and transparent antifouling coating, and an LED light source system, wherein the sealed shell is provided with a lens assembly, an optical assembly, and a first radiator assembly; the LED light source system comprises a microlens array molded from the resin, an array of LED chips, a second radiator assembly and a second fan.

2. The novel LCD projector according to claim 1, wherein the imaging system of the sealed shell comprises a bottom shell and a first face shell; a first fan, a heat absorption end of the first radiator assembly, a first retroreflector, a second Fresnel lens, a liquid crystal display, and a reflective polarizing film are installed in the shell; the heat absorption end of the first radiator assembly is installed at the side of the air outlet of the liquid crystal display; the outside of the shell is provided with a heat dissipation end of the first radiator assembly, an illumination assembly and a light source assembly, and the heat dissipation end of the first radiator assembly is installed at the side of the air inlet of the second fan.

3. The novel LCD projector according to claim 1, wherein the optical assembly and the illumination assembly comprise a first retroreflector, a second Fresnel lens, a reflective polarizing film, a liquid crystal display, a first Fresnel lens, a second retroreflector with a ¼ wave plate, and a lens assembly; the liquid crystal display, the second Fresnel lens, the first retroreflector, and the lens assembly are sequentially installed at one side of the reflective polarizing film; the first retroreflector is obliquely disposed at one side of the reflective polarizing film, and the reflective surface of the first retroreflector is disposed directly facing the lens assembly; the first Fresnel lens, the light source assembly, and the second retroreflector with a ¼ wave plate are disposed at the other side of the reflective polarizing film, and the light source assembly and the second retroreflector with a ¼ wave plate are arranged in parallel.

4. The novel LCD projector according to claim 1, wherein the sealed shell comprises a bottom shell and a first face shell, and a sheet metal is mounted at the top of the first face shell.

5. The novel LCD projector according to claim 1, wherein the microlens array is molded from the resin.

6. The novel LCD projector according to claim 1, wherein the heat dissipation end of the first radiator and the second radiator share the air channel and the second fan.

7. The novel LCD projector according to claim 1, wherein the reflective polarizing film is a part of the sealed shell and is not parallel to the liquid crystal display, and a small included angle is formed between the reflective polarizing film and the liquid crystal display.

8. The novel LCD projector according to claim 1, wherein the transparent antifouling coating is applied to the reflective polarizing film and the first Fresnel lens.

9. The novel LCD projector according to claim 1, wherein the second retroreflector with a ¼ wave plate may be a flat retroreflector or a curved retroreflector.

10. The novel LCD projector according to claim 2, wherein the light source assembly comprises an LED array with microlenses, a second radiator and a second fan; the divergent lights emitted by the light source are irradiated on the first Fresnel lens after passing through the microlens, then are irradiated on the reflective polarizing film after being converted into the parallel light through the first Fresnel lens; S light is transmitted, and P light is reflected; the reflected P light is converged on the second retroreflector with a ¼ wave plate through the first Fresnel lens.

11. The novel LCD projector according to claim 10, wherein each of the LED chips in the LED array of the light source assembly is provided with a microlens, and the microlens is a freeform lens which converges the lights emitted by the LED chip into uniform faculae with the shape and size of the liquid crystal display.
